(19) United States
(12) Patent Application Publication
(10) Pub. No.: US 2021/0175313 A1
(43) Pub. Date: Jun. 10, 2021

(54) ORGANIC LIGHT-EMITTING DIODE DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Sisi ZHOU, Wuhan (CN)

(21) Appl. No.: 16/812,880

(22) Filed: Mar. 9, 2020

(30) Foreign Application Priority Data
Dec. 6, 2019 (CN) 201911238605.3

(51) Int. Cl. H01L 27/32; H05K 1/18

(52) U.S. Cl. CPC H01L 27/3276; H01L 27/3246; H01L 51/0097; H05K 2201/10128; H05K 1/189

(57) ABSTRACT

An organic light-emitting diode display panel, including a display area, a non-display area. A plurality of different film layers are disposed in the display area and the non-display area. A flexible printed circuit board is disposed in the non-display area. An anisotropic conductive film is configured to attach the display panel with the flexible printed circuit board. A barrier is disposed on a side of the display panel adjacent to the non-display area. A barrier covers one or more different film layers, and is configured to prevent the anisotropic conductive film from overflowing from an edge of the non-display area.

### CROSS REFERENCE TO RELATED APPLICATIONS

This application claims the priority of a Chinese Patent Application No. 201911238605.3, filed on Dec. 6, 2019, titled “ORGANIC LIGHT EMITTING DIODE DISPLAY PANEL AND DISPLAY DEVICE”, the entire contents of which are incorporated herein by reference.

### FIELD OF DISCLOSURE

The present disclosure relates to the field of displays, and particularly to organic light-emitting diode (OLED) display panels.

### BACKGROUND

An existing OLED display panels has a profound impact on applications of wearable devices due to its low power consumption and flexible characteristics. In the future, flexible screens will be widely used with a continuous penetration of personal smart terminals. However, during a production process of the OLED display panel, an anisotropic conductive film (ACF) disposed between a display panel and a flexible printed circuit board on the display panel is melted by heat, and it will overflow from the display panel and flow to an edge of the display panel, and then it will cause a polyimide flexible layer and a base substrate of the display panel are adhered, which makes it difficult to use a laser to separate the polyimide flexible layer from the base substrate, and even the two cannot be separated from each other.

Therefore, in an existing OLED display panel technology, the existing OLED display panel lacks a structure capable of preventing the anisotropic conductive film from overflowing the display area of the display panel during a manufacturing process of the OLED display panel, so that the polyimide flexible layer and the base substrate of the display panel are easily adhered. It is difficult to separate them, which affects a subsequent production process and a display quality of the display panel. This urgently needs improvement.

### SUMMARY OF DISCLOSURE

The present disclosure relates to an OLED display panel, which can solve problems in the prior art, such as an existing OLED display panel lacks a structure capable of preventing an anisotropic conductive film from overflowing a display area of the display panel during a manufacturing process of the OLED display panel, so that a polyimide flexible layer and a base substrate of the display panel are easily adhered. It is difficult to separate them, which affects a subsequent production process and a display quality of the display panel.

To solve the above problems, technical solutions provided by the present disclosure are as follows.

The present disclosure provides an organic light-emitting diode (OLED) display panel, including a display area, a non-display area, a plurality of different film layers, a flexible printed circuit board, an anisotropic conductive film, and a barrier.

The plurality of different film layers are disposed in the display area and the non-display area.

The flexible printed circuit board is disposed in the non-display area. The anisotropic conductive film is configured to attach the display panel with the flexible printed circuit board.

The barrier is disposed on a side of the display panel adjacent to the non-display area. The barrier covers one or more different film layers, and is configured to prevent the anisotropic conductive film from overflowing from an edge of the non-display area.

According to one embodiment of the present disclosure, the barrier includes a retaining wall structure and a groove.

According to one embodiment of the present disclosure, a thickness of the retaining wall structure is equal to a depth of the groove.

According to one embodiment of the present disclosure, a shape of the groove includes rectangular, V-shaped, and inverted trapezoidal; and a shape of the retaining wall structure includes rectangular, triangular, and trapezoidal.

According to one embodiment of the present disclosure, the plurality of different film layers are made of one selected from the group consisting of a planarization layer, an insulating layer, a first gate insulating layer, a second gate insulating layer, a buffer layer, and a polyimide flexible layer.

According to one embodiment of the present disclosure, the OLED display panel further includes a pixel definition layer including a first pixel definition layer, a second pixel definition layer, and a third pixel definition layer. The second pixel definition layer is disposed between the first pixel definition layer and the third pixel definition layer, a thickness of the first pixel definition layer is equal to a thickness of the third pixel definition layer, and a thickness of the second pixel definition layer is less than the thickness of the first pixel definition layer or the thickness of the third pixel definition layer.

According to one embodiment of the present disclosure, a number of barriers is greater than or equal to one.

According to one embodiment of the present disclosure, an upper surface of the barrier is flush with a lower surface of the flexible printed circuit board.

According to one embodiment of the present disclosure, the OLED display panel further includes a first side, a second side, a third side, and a fourth side, and the barrier is parallel to the second side and the fourth side of the display panel.

According to one embodiment of the present disclosure, the OLED display panel further includes a driver chip disposed on a surface of the flexible printed circuit board facing away from the display panel.

In comparison with the prior art, advantages of the OLED display panel of the present disclosure are as follows.

In the OLED display panel of the present disclosure, by setting the barrier in the display panel, the barrier covers the plurality of different film layers, and is configured to prevent the anisotropic conductive film from overflowing from the display panel, thereby reducing a difficulty of subsequent processing, and avoiding affecting a display quality of the display panel.

The barrier includes a groove and a retaining wall structure. Numbers of film layers covered by the groove and the retaining wall structure are the same. That is, the depth of the groove is equal to the thickness of the retaining wall structure. A combination of one or more different film layers including the pixel definition layer can improve an adhesion stability between the display panel and the flexible printed circuit board and effectively prevent the anisotropic conductive film overflowing from the edge of the non-display area, which will affect the display quality of the display panel.

### BRIEF DESCRIPTION OF DRAWINGS

To describe the technical solutions in the embodiments of the disclosure or in the prior art more clearly, the following briefly introduces the accompanying drawings required for describing the embodiments. Apparently, the accompanying drawings in the following description show merely some embodiments of the disclosure, and a person of ordinary skill in the art may still derive other drawings from these accompanying drawings without creative efforts.

FIG. 1 is a first plan view of an OLED display panel according to an embodiment of the present disclosure.

FIG. 2 is a second plan view of an OLED display panel according to an embodiment of the present disclosure.

FIG. 3 is a schematic diagram showing a first internal film layers of an OLED display panel according to an embodiment of the present disclosure.

FIG. 4 is a schematic diagram showing a second internal film layers of an OLED display panel according to an embodiment of the present disclosure.

FIG. 5 is a schematic diagram showing a third internal film layers of an OLED display panel according to an embodiment of the present disclosure.

FIG. 6 is a schematic diagram showing a fourth internal film layers of an OLED display panel according to an embodiment of the present disclosure.

FIG. 7 is a schematic diagram showing a fifth internal film layers of an OLED display panel according to an embodiment of the present disclosure.

FIG. 8 is a schematic diagram showing a sixth internal film layers of an OLED display panel according to an embodiment of the present disclosure.

FIG. 9 is a schematic diagram showing a seventh internal film layers of an OLED display panel according to an embodiment of the present disclosure.

FIG. 10 is a schematic diagram showing an eighth internal film layers of an OLED display panel according to an embodiment of the present disclosure.

### DETAILED DESCRIPTION

The following clearly and completely describes the technical solutions in the embodiments of the present disclosure with reference to the accompanying drawings in the embodiments of the present disclosure. Apparently, the described embodiments are merely some but not all of the embodiments of the present disclosure. All other embodiments obtained by a person skilled in the art based on the embodiments of the present disclosure without creative efforts shall fall within the protection scope of the present disclosure.

In the specification of the present disclosure, it is to be understood that terms such as “central”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, and “counterclockwise” should be construed to refer to the orientation as then described or as shown in the drawings under discussion. These relative terms are for convenience of description and do not require that the present disclosure be constructed or operated in a particular orientation. In addition, terms such as “first” and “second” are used herein for purposes of description and are not intended to indicate or imply relative importance or significance or to imply the number of indicated technical features. Thus, the feature defined with “first” and “second” may include one or more of this feature. In the description of the present disclosure, “a plurality of” means two or more than two, unless specified otherwise.

In the description of the present disclosure, it should be understood that, unless specified or limited otherwise, the terms “mounted,” “connected,” “coupled,” and “fixed” are used broadly, and may be, for example, fixed connections, detachable connections, or integral connections, may also be mechanical or electrical connections, may also be direct connections or indirect connections via intervening structures, may also be inner communications of two elements, which can be understood by those skilled in the art according to specific situations.

In the present disclosure, unless specified or limited otherwise, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature. A first feature “below,” “under,” or “on bottom of” a second feature may include an embodiment in which the first feature is right or obliquely “below,” “under,” or “on bottom of” the second feature, or just means that the first feature is at a height lower than that of the second feature.

Various embodiments and examples are provided in the following description to implement different structures of the present disclosure. In order to simplify the present disclosure, certain elements and settings will be described. However, these elements and settings are only by way of example and are not intended to limit the present disclosure. In addition, reference numerals may be repeated in different examples in the present disclosure. This repeating is for the purpose of simplification and clarity and does not refer to relations between different embodiments and/or settings. Furthermore, examples of different processes and materials are provided in the present disclosure. However, it would be appreciated by those skilled in the art that other processes and/or materials may be also applied.

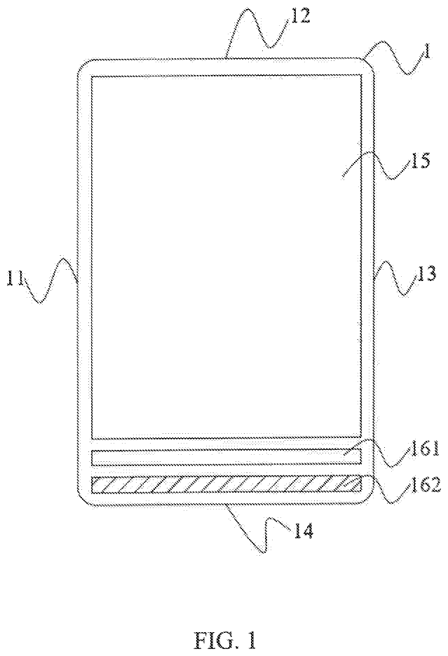

The present disclosure provides an OLED display panel, as shown in FIG. 1 to FIG. 10.

For an existing display panel, an anisotropic conductive film between the display panel and a flexible printed circuit board on the display panel is easily melted by heat. After melting of anisotropic conductive film, it will overflow from the display panel and flow to an edge of the display panel, and then it will cause a polyimide flexible layer and a base substrate of the display panel are adhered, which makes it difficult to use a laser to separate the polyimide flexible layer from the base substrate, and even the two cannot be separated from each other. Therefore, in order to avoid affecting the subsequent production process and display quality of the display panel, the present disclosure provides an OLED display panel. By setting a groove and a retaining wall structure at an edge where the display panel contacts a flexible printed circuit board, an anisotropic conductive film between the display panel and the flexible printed circuit board can be prevented from overflowing out of an edge of the display panel.

Referring to FIG. 1, which is a first plan view of an OLED display panel 1 according to an embodiment of the present disclosure. The display panel 1 is rectangular and includes four sides, namely a first side 11, a second side 12, a third side 13, and a fourth side 14. The display panel is further provided with a display area 15 and a non-display area 16 (not shown in the figure), and a plurality of different film layers are disposed in the display area and the non-display area. The display area 15 is also rectangular. A barrier, including a groove 161 and a retaining wall structure 162, is disposed on a side of the display panel adjacent to the non-display area 16. The barrier covers one or more different film layers for blocking an anisotropic conductive film (not shown in the figure) from overflowing from an edge of the non-display area. In an embodiment of the present disclosure, shapes of a top view of the groove 161 and the retaining wall structure 162 are rectangular and parallel to the second side 12 and the fourth side 14 of the display panel 1.

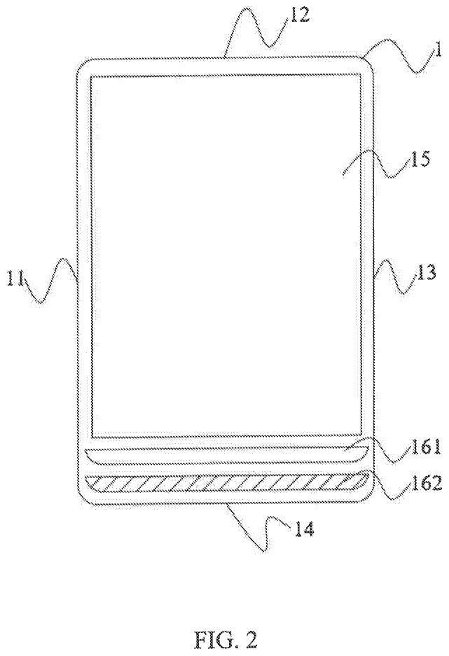

Referring to FIG. 2, which is a second plan view of an OLED display panel according to an embodiment of the present disclosure. Edges of the groove 161 and the retaining wall structure 162 are the same rounded structures as four corners of the display panel 1. The anisotropic conductive film in the display panel can be better prevented from overflowing from the fourth side 14, a corner between the fourth side 14 and the first side 11, and a corner between the fourth side 14 and the third side 13 of the display panel 1.

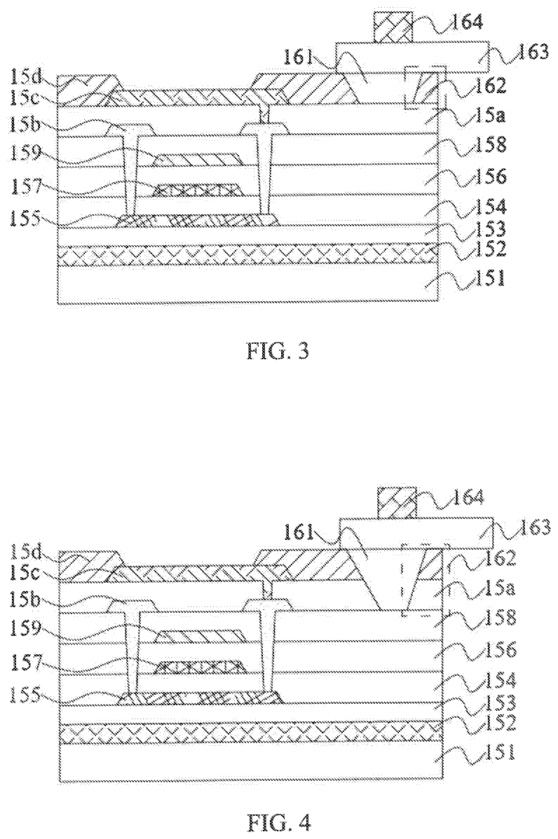

Referring to FIG. 3, which is a schematic diagram showing a first internal film layers of an OLED display panel according to an embodiment of the present disclosure. In an embodiment of the present disclosure, internal film layers of the display panel 1 include a substrate 151, a polyimide flexible layer 152, a buffer layer 153, a first gate insulating layer 154, a semiconductor channel layer 155, a second gate insulating layer 156, a gate layer 157, an insulating layer 158, a display drive capacitor upper substrate 159, a planarization layer 15a, a source/drain layer 15b, an anode layer 15c, a pixel definition layer 15d, a flexible printed circuit board 163, a driver chip 164.

A plurality of film layers are deposited on the substrate 151, and the substrate 151 may be a rigid substrate or a flexible substrate, preferably a flexible substrate.

The polyimide flexible layer 152 is disposed on one side of the substrate 151 and is formed by coating polyimide.

The buffer layer 153 is disposed on a surface of the polyimide flexible layer 152 facing away from the substrate 151, and generally is made of silicon nitride.

The first gate insulating layer 154 is disposed on a surface of the buffer layer 153 facing away from the polyimide flexible layer 152.

The semiconductor channel layer 155 is disposed in the first gate insulating layer 154 and is adjacent to one side of the buffer layer, and two ends of the semiconductor channel layer 155 generally need to be ion-doped.

The second gate insulating layer 156 is disposed on a surface of the first gate insulating layer 154 facing away from the buffer layer 153.

The gate layer 157 is disposed in the second gate insulating layer 156 and is adjacent to the first gate insulating layer 154. The gate layer 157 serves as a lower substrate for a display driving capacitor, and is configured to provide a scanning signal to a thin film transistor of the display panel.

The insulating layer 158 is disposed on a surface of the second gate insulating layer 156 facing away from the first gate insulating layer 154. The insulating layer 158 is an inorganic layer for separating the source/drain layer 15b from the display drive capacitor upper substrate 159.

The display drive capacitor upper substrate 159 is disposed in the insulating layer 158 and is adjacent to a side of the second gate insulating layer 156. The display drive capacitor upper substrate 159 and the gate layer 157 together form a capacitance of a display driving circuit.

The planarization layer 15a is disposed on a surface of the insulating layer 158 facing away from the second gate insulating layer 156, so as to flatten a surface of the source/drain layer 15b.

The source/drain layer 15b is disposed inside the planarization layer 15a. The source/drain layer 15b extends through the insulating layer 158, the second gate insulating layer 156, and the first gate insulating layer 154, and is connected to an active layer 155.

The anode layer 15c is disposed on a surface of the planarization layer 15a facing away from the insulating layer 158, and is in electrical connection with the source/drain layer 15b.

The pixel definition layer 15d is disposed on the surface of the planarization layer 15a facing away from the inducing layer 158 and covers the anode layer 15c. The pixel definition layer 15d is configured to define an evaporation area of an organic light-emitting material and separate R/G/B light-emitting units.

The flexible printed circuit board 163 is disposed at an edge of the non-display area 16 of the display panel 1 near the fourth side 14 of the display panel 1 and is connected to the display panel 1 through an isotropic conductive film (not shown).

The driver chip 164 is disposed on a surface of the flexible printed circuit board 163 facing away from the display panel 1.

Furthermore, the groove 161 and the retaining wall structure 162 are disposed at an end of the non-display area of the display panel 1 near the fourth side 14 of the display panel I. The groove is configured to fill with the anisotropic conductive film. The retaining wall structure 162 is configured to prevent the anisotropic conductive film from overflowing from the display panel 1. A depth of the groove 161 is the same as a thickness of the retaining wall structure 162. In an embodiment of the present disclosure, the groove 161 and the retaining wall structure 162 are disposed at the pixel definition layer 15d, that is, the depth of the groove 161 and the thickness of the retaining wall structure 162 are less than or equal to a thickness of the pixel definition layer 15d. A shape of groove 161 includes inverted trapezoid, and a shape of retaining wall structure 162 includes trapezoidal. In other embodiments of the present disclosure, the shape of groove 161 may also be a rectangle or a V-shaped, the shape of the retaining wall structure 162 may be a rectangle or a triangle. The trapezoid can also be an isosceles trapezoid, a right-angle trapezoid, or an asymmetric trapezoid, and is not limited to the shape shown in FIG. 4. When the shape of the retaining wall structure 162 is trapezoidal, the larger the number of film layers covered by the retaining wall structure 162, the larger the width of the film layers located at a bottom layer, and the smaller the width of the film layers located at an upper layer. The film layers include the pixel definition layer 15d, the planarization layer 15a, the insulating layer 158, the second gate insulating layer 156, the first gate insulating layer 154, the flexible layer 153, and the polyimide flexible layer 152 in this order from top to bottom. When the shape of the retaining wall structure 162 is a triangle, the change of the width of the film layers is the same as the change of the film layers when the retaining wall structure 162 is a trapezoid. When the shape of the retaining wall structure 162 is rectangular, the width of the film layers at the bottom and the width of the film layers at the top are equal.

In another embodiment of the present disclosure, the groove 161 and the retaining wall structure 162 cover the pixel definition layer 15d and the planarization layer 15a. That is, the depth of the groove 161 and the thickness of the retaining wall structure 162 are less than or equal to a sum of thicknesses of the pixel definition layer 15d and the planarization layer 15a, as shown in FIG. 4.

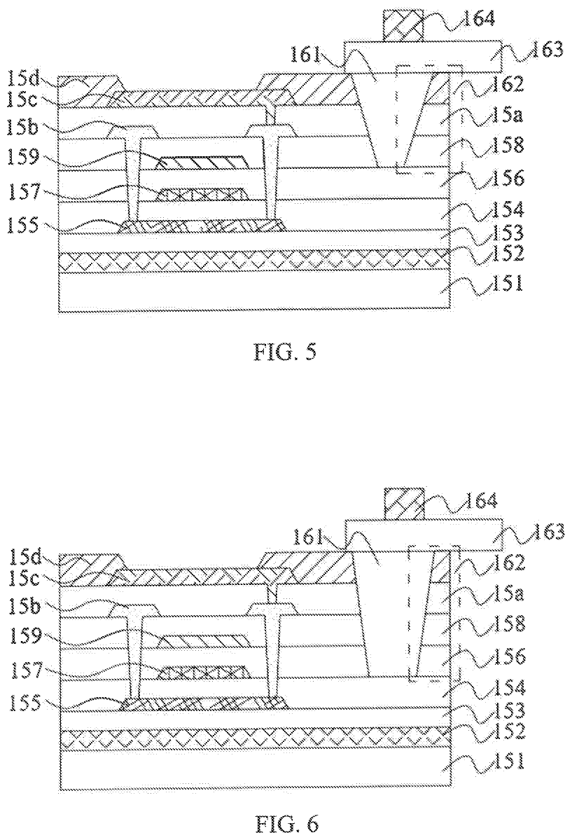

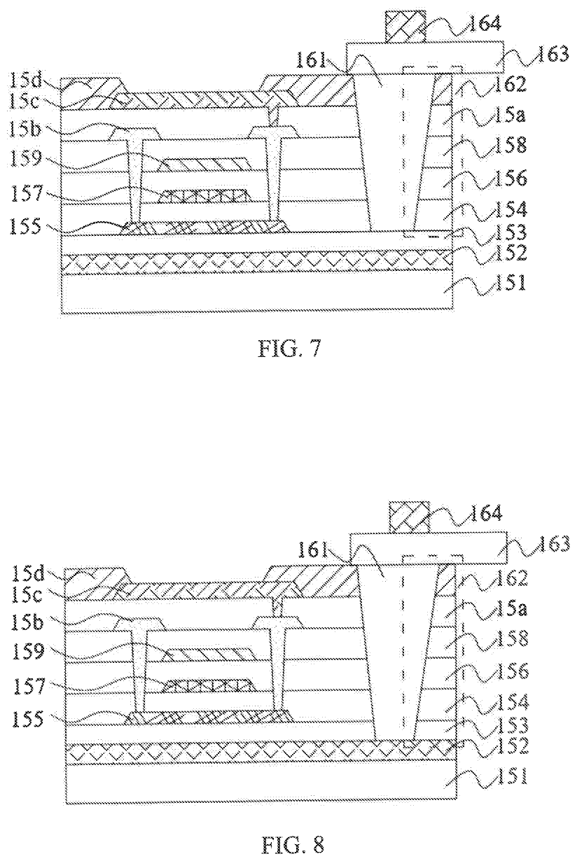

In other embodiments of the present disclosure, the groove 161 and the retaining wall structure 162 may cover the pixel definition layer 15d, the planarization layer 15a, and the insulating layer 158, that is, the depth of the groove 161 and the thickness of the retaining wall structure 162 are less than or equal to a sum of thicknesses of the pixel definition layer 15d, the planarization layer 158, and the insulating layer 156, as shown in FIG. 5. The groove 161 and the retaining wall structure 162 may also cover the pixel definition layer 15d, the planarization layer 15a, the insulating layer 158, and the second gate insulating layer 156, that is, the depth of groove 161 and the thickness of the retaining wall structure 162 is less than or equal to a sum of thicknesses of the pixel definition layer 15d, the planarization layer 15a, the insulating layer 158, and the second gate insulating layer 156, as shown in FIG, 6. The groove 161 and the retaining wall structure 162 may also cover the pixel definition layer 15d, the planarization layer 15a, the insulating layer 158, the second gate insulating layer 156, and the first gate insulating layer 154, that is, the depth of groove 161 and the thickness of the retaining wall structure 162 is less than or equal to a sum of thicknesses of the pixel definition layer 15d, the planarization layer 15a, the insulating layer 158, the second gate insulating layer 156, and the first gate insulating layer 154, as shown in FIG. 7, The groove 161 and the retaining wall structure 162 may also cover the pixel definition layer 15d, the planarization layer 15a, the insulating layer 158, the second gate insulating layer 156, the first gate insulating layer 154, and the buffer layer 153, that is, the depth of groove 161 and the thickness of the retaining wall structure 162 is less than or equal to a sum of thicknesses of the pixel definition layer 15d, the planarization layer 15a, the insulating layer 158, the second gate insulating layer 156, the first gate insulating layer 154, and the buffer layer 153, as shown in FIG. 8, The groove 161 and the retaining wall structure 162 may also cover the pixel definition layer 15d, the planarization layer 15a, the insulating layer 158, the second gate insulating layer 156, the first gate insulating layer 154, the buffer layer 153, and the polyimide flexible layer 152, that is, the depth of groove 161 and the thickness of the retaining wall structure 162 is less than or equal to a sum of thicknesses of the pixel definition layer 15d, the planarization layer 15a, the insulating layer 158, the second gate insulating layer 156, the first gate insulating layer 154, the buffer layer 153, and the polyimide flexible layer 152, as shown in FIG. 9. That is, the groove 161 and the retaining wall structure 162 may cover one or a combination of the pixel definition layer 15d, the planarization layer 15a, the insulating layer 158, the second gate insulating layer 156, the first gate insulating layer 154, the buffer layer 153, and the polyimide flexible layer 152

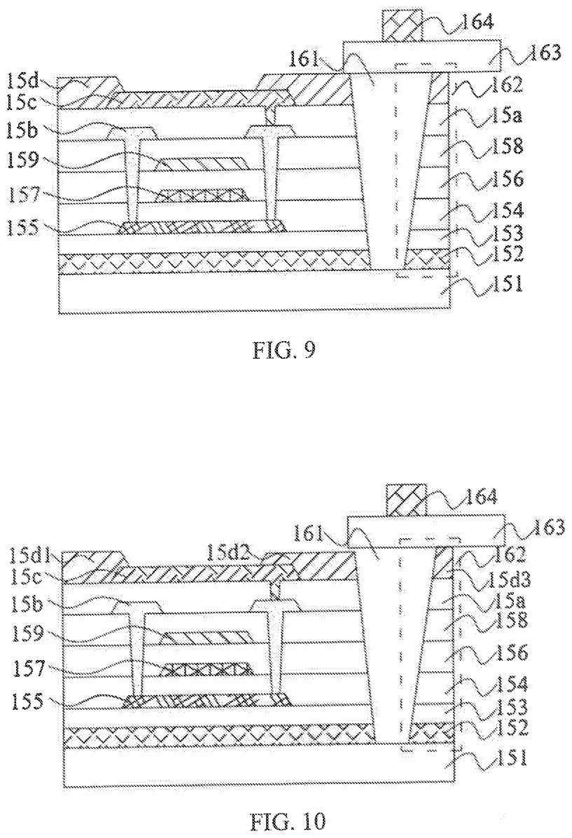

Furthermore, the pixel definition layer 15d includes a first pixel definition layer 15d1, a second pixel definition layer 15d2, and a third pixel definition layer 15d3. A thickness of the first pixel definition layer 15d1 is equal to a thickness of the third pixel definition layer 15d3. In an embodiment of the present disclosure, a thickness of the second pixel definition layer 15d2 is slightly less than the thickness of the first pixel definition layer 15d1 or the thickness of the third pixel definition layer 15d3, so that the anisotropic conductive film flows into the groove 161, as shown in FIG. 10. in another embodiment, the thickness of the second pixel definition layer 15d2 is equal to the thickness of the first pixel definition layer 15d1 or the thickness of the third pixel definition layer 15d3.

Furthermore, a number of the barriers may be one or more, so as to enhance a blocking of the anisotropic conductive film. An upper surface of the barrier is flush with a lower surface of the flexible printed circuit board 163. That is, if the thickness of the second pixel definition layer 15d2 is equal to the thickness of the third pixel definition layer 15d3, the upper surface of the barrier is an upper surface of the pixel definition layer 15d, and the lower surface of the flexible printed circuit board 163 is flush with the upper surface of the pixel definition layer 15d. If the thickness of the second pixel definition layer 15d2 is less than the thickness of the third pixel definition layer 15d3, the lower surface of the flexible printed circuit board 163 is flush with an upper surface of the third pixel definition layer 15d3.

The present disclosure also provides a manufacturing method of an OLED display panel, including the following steps.

In a step S10, a substrate is provided.

In a step S20, a polyimide flexible layer, a buffer layer, a first gate insulating , a semiconductor channel layer, a second gate insulating layer, a gate layer, an insulating layer, a display drive capacitor upper substrate, a planarization layer, a source/drain layer, an anode layer, and a pixel definition layer are sequentially deposited on the substrate.

In a step S30, a surface of the pixel definition layer facing away from the anode layer is patterned by using a fine mask, and then it is exposed and developed to remove a part that is not shield by the fine mask to form a groove and a retaining wall structure.

In a step S40, the flexible printed circuit board is adhered to an end of the display panel near the non-display area by using an anisotropic conductive film.

Furthermore, in the step S20, the source/drain layer is electrically connected to the semiconductor channel layer by etching. The anode layer is electrically connected to the source/drain layer. The fine mask described in the above step S30 is made by using a shape of fine mask according to shapes of the groove and the retaining wall structure.

The OLED display panel provided in the embodiments of the present disclosure are described in detail above. The principle and the implementation manner of the present disclosure are described herein through specific examples in the specification. The description about the embodiments is merely provided to help understand the technical solutions and core ideas of the present disclosure. It should be understood by those skilled in the art that modification can be made to the technical solutions recited in the embodiments described above, or equivalent substitution can be made onto a part of technical features of the technical solution. The modification and equivalent substitution cannot make essence of the technical solutions depart from spirit and a scope of the technical solutions according to the embodiments of the present disclosure.

What is claimed is:

1. An organic light-emitting diode (OLED) display panel, comprising:
a display area;
a non-display area;
a plurality of different film layers disposed in the display area and the non-display area;
a flexible printed circuit board disposed in the non-display area;
an anisotropic conductive film configured to attach the display panel with the flexible printed circuit board; and
a barrier disposed on a side of the display panel adjacent to the non-display area, wherein the barrier covers one or more different film layers, and is configured to prevent the anisotropic conductive film from overflowing from an edge of the non-display area.

2. The OLED display panel as claimed in claim 1, wherein the barrier comprises a retaining wall structure and a groove.

3. The OLED display panel as claimed in claim 2, wherein a thickness of the retaining wall structure is equal to a depth of the groove.

4. The OLED display panel as claimed in claim 2, wherein a shape of the groove comprises rectangular, V-shaped, and inverted trapezoidal; and a shape of the retaining wall structure comprises rectangular, triangular, and trapezoidal.

5. The OLED display panel as claimed in claim 1, wherein the plurality of different film layers are made of one selected from the group consisting of a planarization layer, an insulating layer, a first gate insulating layer, a second gate insulating layer, a buffer layer, and a polyimide flexible layer.

6. The OLED display panel as claimed in claim 5, further comprising a pixel definition layer comprising a first pixel definition layer, a second pixel definition layer, and a third pixel definition layer, wherein the second pixel definition layer is disposed between the first pixel definition layer and the third pixel definition layer, a thickness of the first pixel definition layer is equal to a thickness of the third pixel definition layer, and a thickness of the second pixel definition layer is less than the thickness of the first pixel definition layer or the thickness of the third pixel definition layer.

7. The OLED display panel as claimed in claim 1, wherein a number of barriers is greater than or equal to one.

8. The OLED display panel as claimed in claim 1, wherein an upper surface of the barrier is flush with a lower surface of the flexible printed circuit board.

9. The OLED display panel as claimed in claim 1, further comprising a first side, a second side, a third side, and a fourth side, wherein the barrier is parallel to the second side and the fourth side of the display panel.

10. The OLED display panel as claimed in claim 1, further comprising a driver chip disposed on a surface of the flexible printed circuit board facing away from the display panel.
